(19) United States
(12) Patent Application Publication
(10) Pub. No.: US 2017/0237415 A1
(43) Pub. Date: Aug. 17, 2017

(54) BUFFER CIRCUIT

(71) Applicant: SK hynix Inc., Icheon-si Gyeonggi-do (KR)

(72) Inventor: Yeonsu JANG, Icheon-si Gyeonggi-do (KR)

(21) Appl. No.: 15/191,121

(22) Filed: Jun. 23, 2016

(30) Foreign Application Priority Data
Feb. 11, 2016 (KR) 10-2016-0015761

(51) Int. Cl. H03K 5/02; H03K 17/687

(52) U.S. Cl. CPC H03K 5/023; H03K 17/687

(57) ABSTRACT

In an embodiment, a buffer circuit may includes a current source circuit, a self-bias generation circuit, a signal input circuit, and a first current sink circuit. The current source circuit may apply current to a first node and a second node in response to a self-bias voltage. The self-bias generation circuit may generate the self-bias voltage which has a voltage level between voltage levels of the first and second nodes. The signal input circuit may control the voltage levels of the first node and the second node in response to a first input signal and a second input signal. The first current sink circuit may control an amount of current flowing from the signal input circuit to a ground terminal in response to an enable signal and the self-bias voltage.

### CROSS-REFERENCES TO RELATED APPLICATION

The present application claims priority under 35 U.S.C. §119(a) to Korean application number 10-2016-0015761 filed on Feb. 11, 2016, in the Korean Intellectual Property Office, which is incorporated herein by reference in its entirety.

### BACKGROUND

### 1. Technical Field

Various embodiments generally relate to a semiconductor integrated circuit, and, more particularly, to a buffer circuit.

### 2. Related Art

A semiconductor integrated circuit may have a circuit that is used to amplify signals and/or to temporarily store information before it is processed when transmitting or receiving the signals/information to or from another semiconductor integrated circuit.

In the communication between a plurality of semiconductor integrated circuits, it is important to amplify a signal without amplifying a noise.

The circuit that is used to amplify signals or to temporarily store information when transmitting or receiving the information may be referred to as a buffer circuit.

### SUMMARY

In an embodiment, a buffer circuit may include a current source circuit, a self-bias generation circuit, a signal input circuit, and a first current sink circuit. The current source circuit may apply current to a first node and a second node in response to a self-bias voltage. The self-bias generation circuit may generate the self-bias voltage which has a voltage level between voltage levels of the first and second nodes. The signal input circuit may control the voltage levels of the first node and the second node in response to a first input signal and a second input signal. The first current sink circuit may control an amount of current flowing from the signal input circuit to a ground terminal in response to an enable signal and the self-bias voltage.

In an embodiment, a buffer circuit receiving first and second input signals and outputting first and second output signals may include a self-bias generation circuit, a current source circuit, a signal input circuit, and a first current sink circuit. The self-bias generation circuit may include first and second resistor elements coupled in series between nodes outputting the first and second output signals. The first and second resistor elements may have the same or substantially the same resistance value. The self-bias generation circuit may generate a self-bias from a node coupling the first and second resistor elements to each other. The current source circuit may include one or more transistors receiving the self-bias as inputs. The signal input circuit may include a transistor pair receiving the first and second input signals. The first current sink circuit may include one or more transistors receiving the self-bias as inputs and one or more transistors being turned on in response to an enable signal.

### BRIEF DESCRIPTION OF THE DRAWINGS

FIG. 1 is a diagram illustrating an example of a buffer circuit in accordance with an embodiment.

FIG. 2 is a diagram illustrating an example of a buffer circuit in accordance with an embodiment.

### DETAILED DESCRIPTION

Hereinafter, a buffer circuit will be described below with reference to the accompanying drawings through various examples of embodiments.

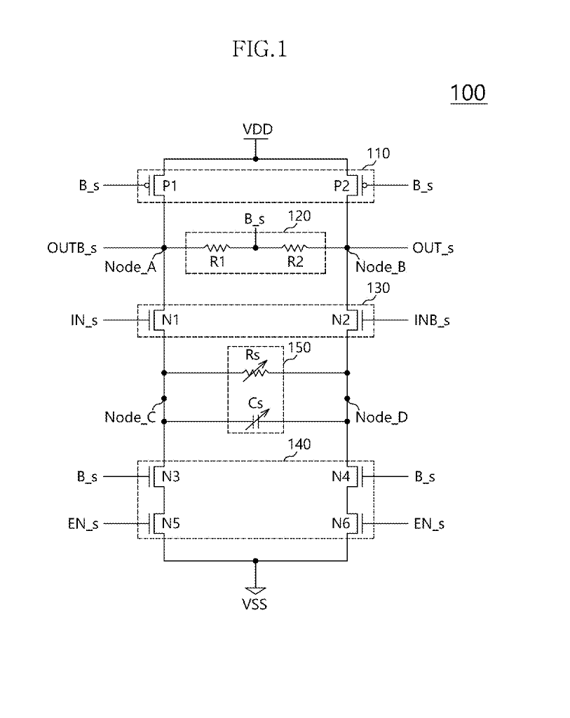

As shown in FIG. 1, a buffer circuit 100 in accordance with an embodiment may include a current source circuit 110, a self-bias generation circuit 120, a signal input circuit 130, and a first current sink circuit 140.

The current source circuit 110 may apply current to the self-bias generation circuit 120 and the signal input circuit 130 in response to a self-bias voltage B_s. For example, in response to the voltage level of the self-bias voltage B_s, the current source circuit 110 may control the amount of current to be applied to the self-bias generation circuit 120 and the signal input circuit 130. In detail, the current source circuit 110 may control the amount of current to be applied to a first node Node_A and a second node Node_B in response to the voltage level of the self-bias voltage B_s. The first node Node_A and the second node Node_B are nodes that couple the current source circuit 110 to the self-bias generation circuit 120 and the signal input circuit 130. Also, the first node Node_A is a node that outputs a first output signal OUTB_s of the buffer circuit 100 therefrom, and the second node Node_B is a node that outputs a second output signal OUT_s of the buffer circuit 100 therefrom. The first node Node_A may be referred to as a first output node Node_A since the first node Node_A is the node from which the first output signal OUTB_s is outputted, and the second node Node_B may be referred to as a second output node Node_B since the second node Node_B is the node from which the second output signal OUT_s is outputted. A voltage level of the first output signal OUTB_s may be different from a voltage level of the second output signal OUT_s. The voltage level of the second output signal OUT_s may decrease if the voltage level of the first output signal OUTB_s increases, and may increase if the voltage level of the first output signal OUTB_s decreases. For example, the first output signal OUTB_s and the second output signal OUT_s may be complementary signals.

The current source circuit 110 may include first and second transistors P1 and P2.

The first transistor P1 applies current to the first node Node_A in response to the voltage level of the self-bias voltage B_s. In detail, the first transistor P1 may control the amount of current to be applied to the first node Node_A, in response to the voltage level of the self-bias voltage B_s. For example, as the voltage level of the self-bias voltage B_s decreases, the first transistor P1 may increase the amount of current to be applied to the first node Node_A, and, as the voltage level of the self-bias voltage B_s increases, the first transistor P1 may decrease the amount of current to be applied to the first node Node_A.

The first transistor P1 has a source receiving an external voltage VDD, a gate receiving the self-bias voltage B_s, and a drain coupled to the first node Node_A.

The second transistor P2 applies current to the second node Node_B in response to the voltage level of the self-bias voltage B_s. In detail, the second transistor P2 may control the amount of current to be applied to the second node Node_B, in response to the voltage level of the self-bias voltage B_s. For example, as the voltage level of the self-bias voltage B_s decreases, the second transistor P2 may increase the amount of current to be applied to the second node Node_B, and, as the voltage level of the self-bias voltage B_s increases, the second transistor P2 may decrease the amount of current to be applied to the second node Node_B.

The second transistor P2 may have a source receiving the external voltage VDD, a gate receiving the self-bias voltage B_s, and a drain coupled to the second node Node_B.

The current source circuit 110 may increase a voltage gain of the buffer circuit 100 by operating in a saturation region in response to the self-bias voltage B_s, and may increase the operation regions of the output signals OUT_s and OUTB_s by decreasing voltage drops at both ends of the first and second transistors P1 and P2.

The self-bias generation circuit 120 may generate the self-bias voltage B_s which has a voltage level between the respective voltage levels of the first node Node_A and the second node Node_B. For example, the self-bias voltage B_s may have an average voltage level of the respective voltage levels of the first node Node_A and the second node Node_B.

The self-bias generation circuit 120 may include first and second resistor elements R1 and R2. The first resistor element R1 may have one end coupled to the first node Node_A and the other end coupled to one end of the second resistor element R2. The second resistor element R2 may have one end coupled to the other end of the first resistor element R1 and the other end coupled to the second node Node_B. The first and second resistor elements R1 and R2 may have the same or substantially the same resistance value, and the self-bias voltage B_s may be generated and output from a node that couples the first and second resistor elements R1 and R2 to each other.

The signal input circuit 130 may lower the voltage level of the first node Node_A in response to a first input signal IN_s, and may lower the voltage level of the second node Node_B in response to a second input signal INB_s. For example, the signal input circuit 130 may provide the current of the first node Node_A to a third node Node_C in response to the first input signal IN_s, and may control the amount of current flowing from the first node Node_A to the third node Node_C in response to the voltage level of the first input signal IN_s. The signal input circuit 130 may provide the current of the second node Node_B to a fourth node Node_D in response to the second input signal INB_s, and may control the amount of current flowing from the second node Node_B to the fourth node Node_D in response to the voltage level of the second input signal INB_s. A voltage level of the first input signal IN_s may be different from a voltage level of the second input signal INB_s. The first and second input signals IN_s and INB_s may be signals which are correlated in such a manner that the voltage level of the second input signal INB_s decreases if the voltage level of the first input signal IN_s increases and the voltage level of the second input signal INB_s increases if the voltage level of the first input signal IN_s decreases. For example, the first and second input signals IN_s and INB_s may be complementary signals. Therefore, the signal input circuit 130 may generate the voltage level of the first node Node_A to be lower than the voltage level of the second node Node_B in a case where the voltage level of the first input signal IN_s is higher than the voltage level of the second input signal INB_s, and may generate the voltage level of the first node Node_A to be higher than the voltage level of the second node Node_B in a case where the voltage level of the first input signal IN_s is lower than the voltage level of the second input signal INB_s.

The signal input circuit 130 may include third and fourth transistors N1 and N2. The third transistor N1 may have a gate receiving the first input signal IN_s, a drain coupled to the first node Node_A, and a source coupled to the third node Node_C. The fourth transistor N2 may have a gate receiving the second input signal INB_s, a drain coupled to the second node Node_B, and a source coupled to the fourth node Node_D.

The first current sink circuit 140 may flow the current of the third and fourth nodes Node_C and Node_D to a ground terminal VSS in response to an enable signal EN_s and the self-bias voltage B_s. For example, the first current sink circuit 140 may flow the current of the third and fourth nodes Node_C and Node_D to the ground terminal VSS in response to the voltage level of the self-bias voltage B_s when the enable signal EN_s is enabled, and as a result the voltage levels of the third and fourth nodes Node_C and Node_D may decrease. As the voltage level of the self-bias voltage B_s, the first current sink circuit 140 may increase the amount of current flowing from the third and fourth nodes Node_C and Node_D to the ground terminal VSS while the enable signal EN_s is being enabled.

The first current sink circuit 140 may include fifth to eighth transistors N3, N4, N5 and N6. The fifth transistor N3 may have a gate receiving the self-bias voltage B_s, and a drain coupled to the third node Node_C. The sixth transistor N4 may have a gate receiving the self-bias voltage B_s, and a drain coupled to the fourth node Node_D is coupled. The seventh transistor N5 may have a gate receiving the enable signal EN_s, a drain coupled to the source of the fifth transistor N3, and a source coupled to the ground terminal VSS. The eighth transistor N6 may have a gate receiving the enable signal EN_s, a drain coupled to the source of the sixth transistor N4, and a source coupled to the ground terminal VSS.

In an embodiment, the buffer circuit 100 may further include an amplification control circuit 150. The amplification control circuit 150 may be coupled between the third and fourth nodes Node_C and Node_D. The amplification control circuit 150 may control the gain of the buffer circuit 100.

The amplification control circuit 150 may include a variable resistor element Rs and a variable capacitor Cs. The variable resistor element Rs may have one end coupled to the third node Node_C and the other end coupled to the fourth node Node_D. The variable capacitor Cs may have one end coupled to the third node Node_C and the other end coupled to the fourth node Node_D.

The amplification control circuit 150 may control the gain of the buffer circuit 100 by varying the resistance value of the variable resistor element Rs and the capacitance value of the variable capacitor Cs.

The buffer circuit 100 in accordance with an embodiment may operate as follows.

The current source circuit 110 may apply current to the first and second nodes Node_A and Node_B in response to the voltage level of the self-bias voltage B_s. The current source circuit 110 may provide a larger amount of current to the first and second nodes Node_A and Node_B as the voltage level of the self-bias voltage B_s becomes lower, and may provide a smaller amount of current to the first and second nodes Node_A and Node_B as the voltage level of the self-bias voltage B_s becomes high.

Here, the self-bias voltage B_s may have the average voltage level of the respective voltage levels of the first and second nodes Node_A and Node_B.

The signal input circuit 130 may control the voltage levels of the first and second nodes Node_A and Node_B in response to the respective voltage levels of the first input signal IN_s and the second input signal INB_s. For example, the signal input circuit 130 lowers the voltage level of the first node Node_A to be lower than the voltage level of the second node Node_B, in the case where the voltage level of the first input signal IN_s is higher than the voltage level of the second input signal INB_s. The signal input circuit 130 raises the voltage level of the first node Node_A to be higher than the voltage level of the second node Node_B, in the case where the voltage level of the first input signal IN_s is lower than the voltage level of the second input signal INB_s.

In other words, the signal input circuit 130 may apply the current applied to the first and second nodes Node_A and Node_B, to the third and fourth nodes Node_C and Node_D, in response to the voltage levels of the first and second input signals IN_s and INB_s. The amount of current flowing through the signal input circuit 130 may vary depending on the voltage levels of the first input signal IN_s and the second input signal INB_s. For example, the amount of current flowing from the first node Node_A to the third node Node_C may be larger than the amount of current flowing from the second node Node_B to the fourth node Node_D, in the case where the voltage level of the first input signal IN_s is higher than the voltage level of the second input signal INB_s. In contrast, the amount of current flowing from the first node Node_A to the third node Node_C may be smaller than the amount of current flowing from the second node Node_B to the fourth node Node_D, in the case where the voltage level of the first input signal IN_s is lower than the voltage level of the second input signal INB_s.

The first current sink circuit 140 may allow the current of the third and fourth nodes Node_C and Node_D to flow to the ground terminal VSS in response to the voltage level of the self-bias voltage B_s when the enable signal EN_s is enabled. For example, as the voltage level of the self-bias voltage B_s, the first current sink circuit 140 may increase the amount of current flowing from the third and fourth nodes Node_C and Node_D to the ground terminal VSS while the enable signal EN_s is being enabled.

The buffer circuit 100 in accordance with an embodiment may generate the first and second output signals OUTB_s and OUT_s in response to the first and second input signals IN_s and INB_s when the enable signal EN_s is enabled. The buffer circuit 100 in accordance with an embodiment may include the current source circuit 110 which controls the amount of current to be applied to the signal input circuit 130, according to the voltage level of the self-bias voltage B_s, and the first current sink circuit 140 which controls the amount of current to flow from the signal input circuit 130 to the ground terminal VSS, according to the voltage level of the self-bias voltage B_s. The current source circuit 110 may increase the amount of current to be applied to the first and second nodes Node_A and Node_B, that is, to the signal input circuit 130, as the voltage level of the self-bias voltage B_s decreases. The current source circuit 110 may decrease the amount of current to be applied to the first and second nodes Node_A and Node_B, that is, to the signal input circuit 130, as the voltage level of the self-bias voltage B_s increases. The first current sink circuit 140 may increase the amount of current flowing from the signal input circuit 130 to the ground terminal VSS, when the voltage level of the self-bias voltage B_s increases, and may decrease the amount of current flowing from the signal input circuit 130 to the ground terminal VSS, when the voltage level of the self-bias voltage B_s decreases.

In summary, in the buffer circuit 100 in accordance with an embodiment, if the voltage levels of the first and second nodes Node_A and Node_B, that is, the first and second output nodes Node_A and Node_B, may decrease according to variations in voltage, process and temperature, the voltage level of the self-bias voltage B_s (e.g., the average voltage level of the first and second output nodes Node_A and Node_B) may also decrease. As the voltage level of the self-bias voltage B_s decrease, the current source circuit 110 may increase current to be supplied to the first and second nodes Node_A and Node_B, that is, to the signal input circuit 130, and the first current sink circuit 140 may decrease the amount of current flowing from the signal input circuit 130 to the ground terminal VSS. Moreover, if the voltage levels of the first and second nodes Node_A and Node_B increase according to variations in voltage, process and temperature, the voltage level of the self-bias voltage B_s may also increase. As the voltage level of the self-bias voltage B_s increases, the current source circuit 110 may decrease current to be applied to the signal input circuit 130, and the first current sink circuit 140 may increase the amount of current flowing from the signal input circuit 130 to the ground terminal VSS.

As a result, in the buffer circuit 100 in accordance with an embodiment, as the self-bias voltage B_s is appropriately varied according to variations in voltage, process and temperature, the first and second output signals OUTB_s and OUT_s generated in response to the first and second input signals IN_s and INB_s may have constant maximum and minimum voltage levels.

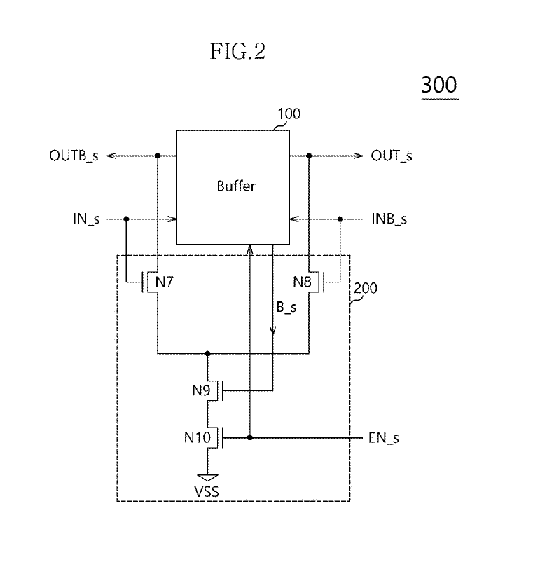

In FIG. 2, a buffer circuit 300 in accordance with an embodiment may include a buffer 100 and a second current sink circuit 200.

Like the buffer 100 illustrated in FIG. 1, the buffer 100 illustrated in FIG. 2 may include a current source circuit 110, a self-bias generation circuit 120, a signal input circuit 130, and a first current sink circuit 140. The current source circuit 110, the self-bias generation circuit 120, the signal input circuit 130 and the first current sink circuit 140 may be configured in the same manner as those illustrated in FIG. 1.

In an embodiment, the second current sink circuit 200 may further provide differential pair transistors to the buffer 100. The second current sink circuit 200 may control the voltage levels of first and second output signals OUTB_s and OUT_s in response to an enable signal EN_s, a self-bias signal B_s and first and second input signals IN_s and INB_s. For example, the second current sink circuit 200 may control the voltage levels of the first and second output signals OUTB_s and OUT_s in response to the self-bias signal B_s and the first and second input signals IN_s and INB_s when the enable signal EN_s is enabled. In detail, the second current sink circuit 200 lowers the voltage level of the first output signal OUTB_s when the voltage level of the first input signal IN_s rises, and lowers the voltage level of the second output signal OUT_s when the voltage level of the second input signal INB_s rises. As the voltage level of the self-bias voltage B_s increases, the voltage levels of the first and second output signals OUTB_s and OUT_s may decrease.

In an embodiment, the second current sink circuit 200 may include ninth to twelfth transistors N7, N8, N9 and N10. The ninth transistor N7 may have a gate receiving the first input signal IN_s, and a drain coupled to a node (e.g., a first node Node_A, see FIG. 1) from which the first output signal OUTB_s is output. The tenth transistor N8 may have a gate receiving the second input signal INB_s, and a drain coupled to a node (e.g., a second node Node_B, see FIG. 1) from which the second output signal OUT_s is output. The eleventh transistor N9 may have a gate receiving the self-bias voltage B_s, and a drain coupled to a node to which the ninth and tenth transistors N7 and N8 are coupled. The twelfth transistor N10 may have a gate receiving the enable signal EN_s, a drain coupled to the source of the eleventh transistor N9, and a source coupled to a ground terminal VSS.

The buffer circuit 300 illustrated in FIG. 2 may also operate in the same manner as the buffer circuit 100 illustrated in FIG. 1. However, unlike the buffer circuit 100 shown in FIG. 1, since the second current sink circuit 200 for controlling the voltage levels of the first and second output signals OUTB_s and OUT_s is additionally provided, a common noise component may be reduced, and the rising timings and falling timings of the first and second output signals OUTB_s and OUT_s may be controlled.

While various embodiments have been described above, it will be understood to those skilled in the art that the embodiments described are examples only. Accordingly, the buffer circuit described herein should not be limited based on the described embodiments.

What is claimed is:

1. A buffer circuit comprising:
a current source circuit configured to apply current to a first node and a second node in response to a self-bias voltage;
a self-bias generation circuit configured to generate the self-bias voltage which has a voltage level between voltage levels of the first and second nodes;
a signal input circuit configured to control the voltage levels of the first node and the second node in response to a first input signal and a second input signal; and
a first current sink circuit configured to control an amount of current flowing from the signal input circuit to a ground terminal in response to an enable signal and the self-bias voltage.

2. The buffer circuit according to claim 1, wherein the current source circuit decreases an amount of current to be applied to the first and second nodes when the voltage level of the self-bias voltage increases, and increases an amount of current to be applied to the first and second nodes when the voltage level of the self-bias voltage decreases.

3. The buffer circuit according to claim 1, wherein the self-bias voltage has an average voltage level of the voltage levels of the first and second nodes.

4. The buffer circuit according to claim 1, wherein the signal input circuit increases an amount of current to flow from the first node to the first current sink circuit, as a voltage level of the first input signal rises, and increases an amount of current to flow from the second node to the first current sink circuit, as a voltage level of the second input signal rises.

5. The buffer circuit according to claim 4, wherein, when the enable signal is enabled, the first current sink circuit allows current applied from the signal input circuit to flow to a ground terminal in response to the voltage level of the self-bias voltage.

6. The buffer circuit according to claim 5, wherein the first current sink circuit increases an amount of current to flow from the signal input circuit to the ground terminal when the enable signal is enabled and the voltage level of the self-bias voltage increases, and decreases an amount of current to flow from the signal input circuit to the ground terminal when the enable signal is enabled and the voltage level of the self-bias voltage decreases.

7. The buffer circuit according to claim 1, wherein:
the current source circuit, the self-bias generation circuit and the signal input circuit are coupled in common to the first and second nodes;
a first output signal is output from the first node, and a second output signal is output from the second node; and
the signal input circuit and the first current sink circuit are coupled to one another through a third node and a fourth node.

8. The buffer circuit according to claim 7, wherein the third node is a node through which current flowing from the first node passes, and the fourth node is a node through which current flowing from the second node passes.

9. The buffer circuit according to claim 8, further comprising an amplification control circuit coupled between the third node and the fourth node.

10. The buffer circuit according to claim 9, wherein the amplification control circuit comprises:
a variable resistor element coupled between the third node and the fourth node; and
a variable capacitor coupled between the third node and the fourth node.

11. The buffer circuit according to claim 7, further comprising:
a second current sink circuit configured to control voltage levels of the first and second output signals in response to the first and second input signals and the self-bias voltage when the enable signal is enabled.

12. The buffer circuit according to claim 11, wherein the second current sink circuit controls a voltage level of the first node in response to the first input signal, controls a voltage level of the second node in response to the second input signal, and controls an amount of current to flow from the first and second nodes to the ground terminal, in response to the self-bias voltage, when the enable signal is enabled.

13. The buffer circuit according to claim 12, wherein the second current sink circuit increases an amount of current to flow from the first node to the ground terminal as voltage levels of the first input signal and the self-bias voltage increase, and increases an amount of current to flow from the second node to the ground terminal as voltage levels of the second input signal and the self-bias voltage increase.

14. The buffer circuit according to claim 1, wherein the current source circuit comprises:
a first transistor having a gate receiving the self-bias voltage, a source receiving an external voltage, and a drain coupled to the first node; and
a second transistor having a gate receiving the self-bias voltage, a source receiving the external voltage, and a drain coupled to the second node, and
wherein a voltage gain of the buffer circuit is increased since the first and second transistors operate in a saturation region by the self-bias voltage, and operation regions of the first and second output signals are increased by decreasing voltage drops at both ends of the first and second transistors.

15. A buffer circuit receiving first and second input signals and outputting first and second output signals, the buffer circuit comprising:
a self-bias generation circuit including first and second resistor elements coupled in series between nodes outputting the first and second output signals, the first and second resistor elements having the same or substantially the same resistance value, self-bias generation circuit generating a self-bias from a node coupling the first and second resistor elements to each other;
a current source circuit including one or more transistors receiving the self-bias as inputs;
a signal input circuit including a transistor pair receiving the first and second input signals; and
a first current sink circuit including one or more transistors receiving the self-bias as inputs and one or more transistors being turned on in response to an enable signal.

16. The buffer circuit according to claim 15, further comprising an amplification control circuit coupled between the signal input circuit and the first current sink circuit.

17. The buffer circuit according to claim 16, wherein the amplification control circuit comprises:
a variable resistor element coupled between the signal input circuit and the first current sink circuit; and
a variable capacitor coupled between the signal input circuit and the first current sink circuit.

18. The buffer circuit according to claim 15, further comprising:
a second current sink circuit including a transistor pair receiving the first and second input signals and the first and second output signals, one or more transistors receiving the self-bias as inputs, and one or more transistors being turned on in response to the enable signal.

19. The buffer circuit according to claim 18, wherein the transistor pair receiving the first and second input signals and the first and second output signals receives the first and second input signals through gates thereof and receives the first and second output signals through drains thereof.
